(19) United States
(12) Patent Application Publication
(10) Pub. No.: US 2018/0358370 A1
(43) Pub. Date: Dec. 13, 2018

(54) SEMICONDUCTOR MEMORY DEVICE AND MANUFACTURING THE SAME

(71) Applicant: Samsung Electronics Co., Ltd., Suwon-si (KR)

(72) Inventors: Sung-Min HWANG, Hwaseong-si (KR); Joon-Sung Lim, Yongin-si (KR)

(73) Assignee: Samsung Electronics Co., Ltd., Suwon-si (KR)

(21) Appl. No.: 15/841,762

(22) Filed: Dec. 14, 2017

(30) Foreign Application Priority Data
Jun. 12, 2017 (KR) 10-2017-0073390

(51) Int. Cl. H01L 27/11573; H01L 27/11524; H01L 27/11556; H01L 27/11529; H01L 27/1157; H01L 27/11582; H01L 23/528; H01L 23/532

(52) U.S. Cl. CPC H01L 27/11573; H01L 27/11524; H01L 27/11556; H01L 23/53271; H01L 27/1157; H01L 27/11582; H01L 23/528; H01L 27/11529

(57) ABSTRACT

Disclosed are a semiconductor memory device and a method of manufacturing the same. The semiconductor memory device includes a cell array region connected to a peripheral circuit region. The cell array region includes a plurality of electrode structures and a plurality of vertical structures on a body conductive layer. The plurality of electrode structures include a plurality of electrodes that are sequentially stacked on the body conductive layer. The plurality of vertical structures penetrate the electrode structures and are connected to the body conductive layer. The peripheral circuit region includes a peripheral transistor on a residual substrate. The residual substrate has a top surface higher than that of the body conductive layer.

### CROSS-REFERENCE TO RELATED APPLICATIONS

This U.S. nonprovisional patent application claims priority under 35 U.S.C § 119 to Korean Patent Application No. 10-2017-0073390 filed on Jun. 12, 2017, the entire contents of which are hereby incorporated by reference.

### BACKGROUND

Inventive concepts relate to a semiconductor device and a method of manufacturing the same, and more particularly, to a three-dimensional nonvolatile memory device and a method of manufacturing the same.

Increasing the integration of semiconductor devices may improve performance, lower manufacturing costs, and lower the prices of products. Integration of typical two-dimensional memory devices is primarily determined by the area occupied by a unit memory cell, such that it is greatly influenced by the level of technology for forming fine patterns. However, the extremely expensive processing equipment needed to increase pattern fineness sets a practical limitation on increasing the integration of two-dimensional memory devices.

### SUMMARY

Some embodiments of inventive concepts provide a simplified method of manufacturing a semiconductor memory device.

Some embodiments of inventive concepts provide a semiconductor memory device whose thickness is reduced.

According to some example embodiments of inventive concepts, a semiconductor memory device may include a cell array region connected to a peripheral circuit region. The cell array region may include a plurality of electrode structures and plurality of vertical structures on a body conductive layer. The plurality of electrode structures each include a plurality of electrodes that are sequentially stacked on the body conductive layer. The plurality of vertical structures penetrate the plurality of electrode structures and are connected to the body conductive layer. The peripheral circuit region may include a peripheral transistor on a residual substrate. A top surface of the residual substrate may be higher than a top surface of the body conductive layer.

According to some example embodiments of inventive concepts, a semiconductor memory device may include a body conductive layer including a polycrystalline semiconductor material; a plurality of electrode structures on the body conductive layer; the plurality of electrode structures including a plurality of electrodes that are sequentially stacked on the body conductive layer; a plurality of vertical structures that penetrate the plurality of electrode structures, the plurality of vertical structures being connected to the body conductive layer; and a common conductive line that extends between the plurality of electrode structures, the common conductive line being connected to the body conductive layer.

According to some example embodiments of inventive concepts, a method of fabricating a semiconductor memory device may include forming an electrode structure and vertical structures on a semiconductor substrate, each of the vertical structures extending into an upper portion of the semiconductor substrate, each of the vertical structures including a data storage layer and a channel semiconductor layer; removing at least a portion of the semiconductor substrate; and forming a body conductive layer connected in common to lower portions of the vertical structures. The removing at least a portion of the semiconductor substrate may include removing a portion of the data storage layer to expose the channel semiconductor layer when the at least portion of the semiconductor substrate is removed.

### BRIEF DESCRIPTION OF THE DRAWINGS

FIG. 1 illustrates a simplified circuit diagram showing a cell array of a semiconductor memory device according to some example embodiments of inventive concepts.

FIG. 2A illustrates a plan view showing a semiconductor memory device according to some example embodiments of inventive concepts.

FIG. 2B illustrates a cross-sectional view taken along line I-I′ of FIG. 2A.

FIGS. 3A and 3B illustrate enlarged views showing section A of FIG. 2B according to some example embodiments of inventive concepts.

FIGS. 4 to 11 illustrate cross-sectional views taken along line I-I′ of FIG. 2A, showing a method of manufacturing a semiconductor memory device according to some example embodiments of inventive concepts.

FIGS. 12 to 19 illustrate cross-sectional views taken along line I-I′ of FIG. 2A, showing a semiconductor memory device according to some example embodiments of inventive concepts.

FIGS. 20 to 22 illustrate cross-sectional views taken along line I-I′ of FIG. 2A, showing a method of manufacturing a semiconductor memory device according to some example embodiments of inventive concepts.

FIGS. 23 to 24 illustrate cross-sectional views showing a method of manufacturing a semiconductor memory device according to some example embodiments of inventive concepts.

FIG. 25 illustrates a cross-sectional view showing a semiconductor package according to some example embodiments of inventive concepts.

### DETAILED DESCRIPTION

It will be hereinafter described in detail some example embodiments of inventive concepts in conjunction with the accompanying drawings.

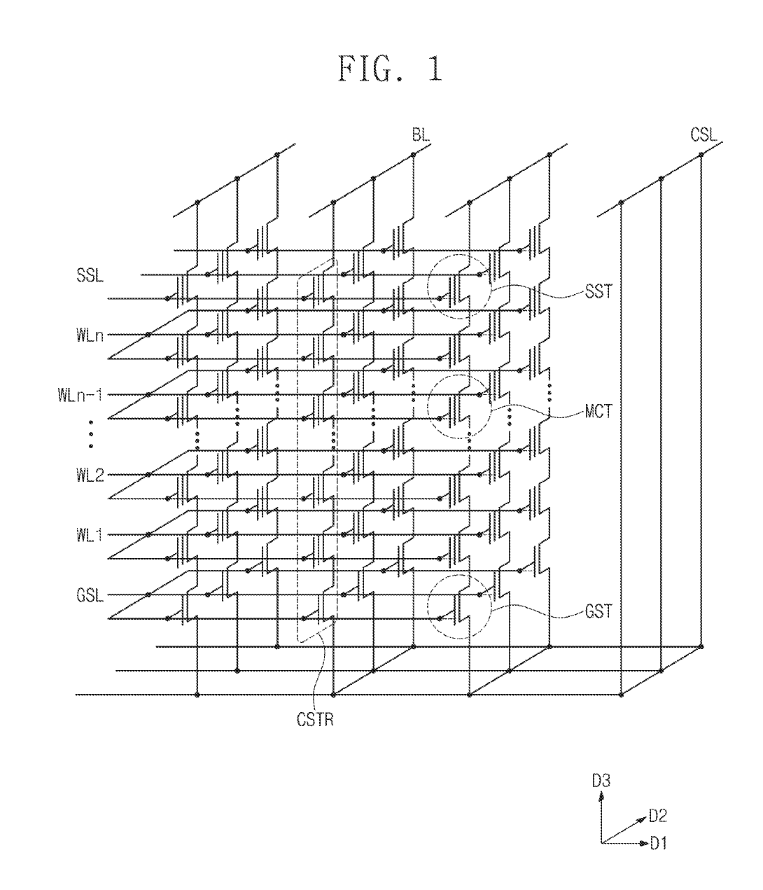

FIG. 1 illustrates a simplified circuit diagram showing a cell array of a semiconductor memory device according to some example embodiments of inventive concepts.

Referring to FIG. 1, a cell array of a semiconductor memory device according to some example embodiments may include a common source line CSL, a plurality of bit lines BL, and a plurality of cell strings CSTR between the common source line CSL and the plurality of bit lines BL.

The common source line CSL may be a conductive thin layer disposed on a substrate or an impurity region formed in the substrate. The bit lines BL may be conductive patterns (e.g., metal lines) spaced apart from and disposed on the substrate. The bit lines BL may be two-dimensionally arranged, and a plurality of cell strings CSTR may be connected in parallel to each of the bit lines BL. The cell strings CSTR may be connected in common to the common source line CSL. For example, a plurality of the cell strings CSTR may be disposed between a plurality of the bit lines BL and the common source line CSL. In some embodiments, the common source line CSL may be provided in plural. The common source lines CSL may be supplied with the same voltage or electrically controlled independently of each other.

Each of the cell strings CSTR may include a ground select transistor GST connected to the common source line CSL, a string select transistor SST connected to the bit line BL, and a plurality of memory cell transistors MCT between the ground and string select transistors GST and SST. The ground select transistor GST, the string select transistor SST, and the memory cell transistors MCT may be connected in series.

The common source line CSL may be connected in common to sources of the ground select transistors GST. In addition, the common source line CSL and the bit lines BL may be provided therebetween with a ground select line GSL, a plurality of word lines WL1 to WLn, and a plurality of string select lines SSL between the common source line CSL and the bit lines BL. The ground select line GSL, the word lines WL1 to WLn, and the string select lines SSL may be used as gate electrodes of the ground select transistor GST, the memory cell transistors MCT, and the string select transistor SST, respectively. Moreover, each of the memory cell transistors MCT may include a data storage element.

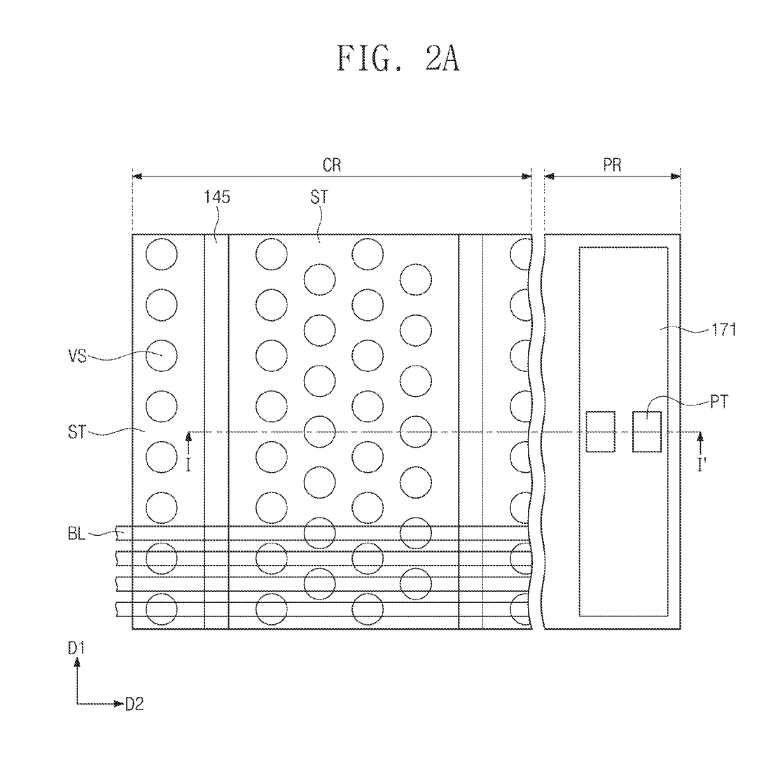

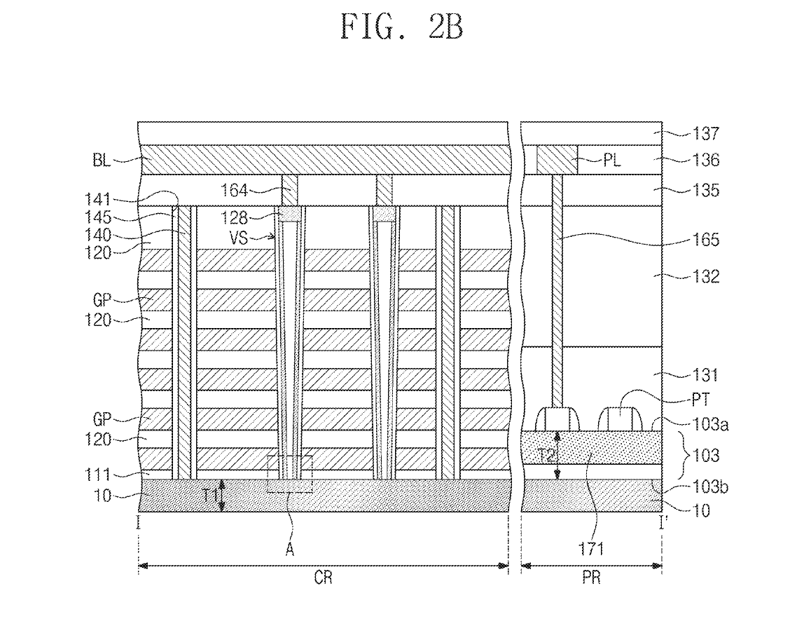

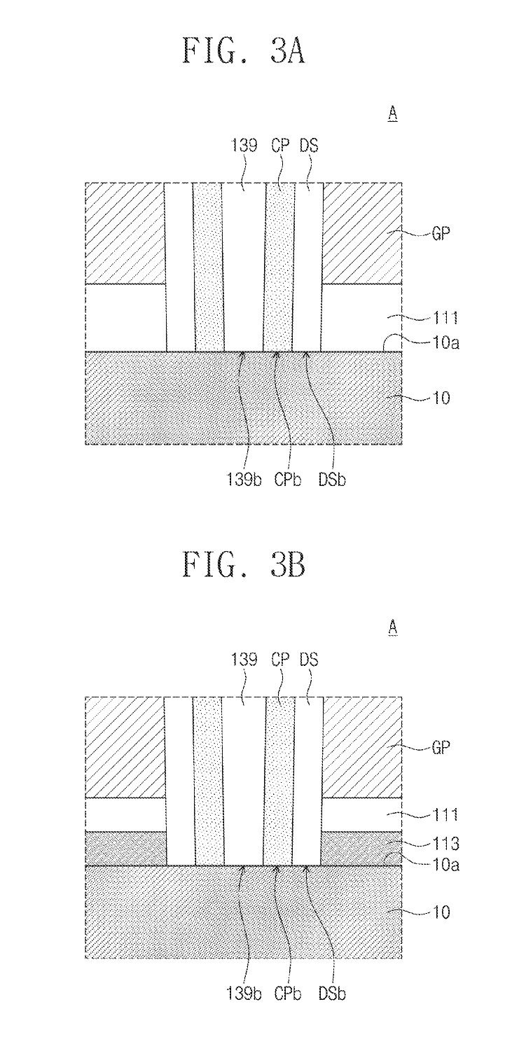

FIG. 2A illustrates a plan view showing a semiconductor memory device according to some example embodiments of inventive concepts. FIG. 2B illustrates a cross-sectional view taken along line I-I′ of FIG. 2A. FIGS. 3A and 3B illustrate enlarged views showing section A of FIG. 2B according to some example embodiments of inventive concepts.

Referring to FIGS. 2A and 2B, a semiconductor memory device may be provided to include a cell array region CR and a peripheral circuit region PR. For example, the semiconductor memory device may be a flash memory device. The cell array region CR may be a zone provided with a plurality of memory cells, and according to some example embodiments of inventive concepts, the cell array of FIG. 1 may be provided on the cell array region CR. The peripheral circuit region PR may be a zone provided with a word line driver, a sense amplifier, row and column decoders, and control circuits. For brevity of description, the peripheral circuit region PR is illustrated to lie on one side of the cell array region CR, but it should be recognized that the peripheral circuit region PR may be additionally disposed at least one of other sides of the cell array region CR. For example, the peripheral circuit region PR may surround the cell array region CR.

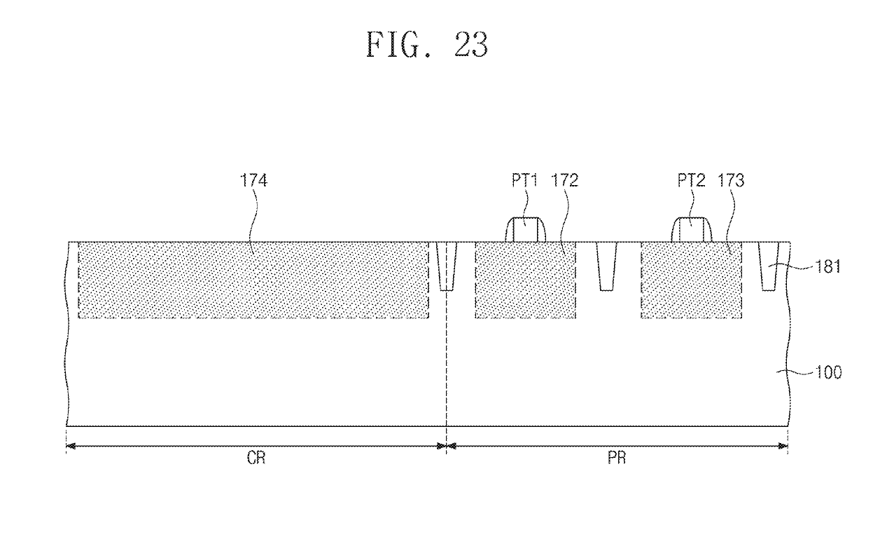

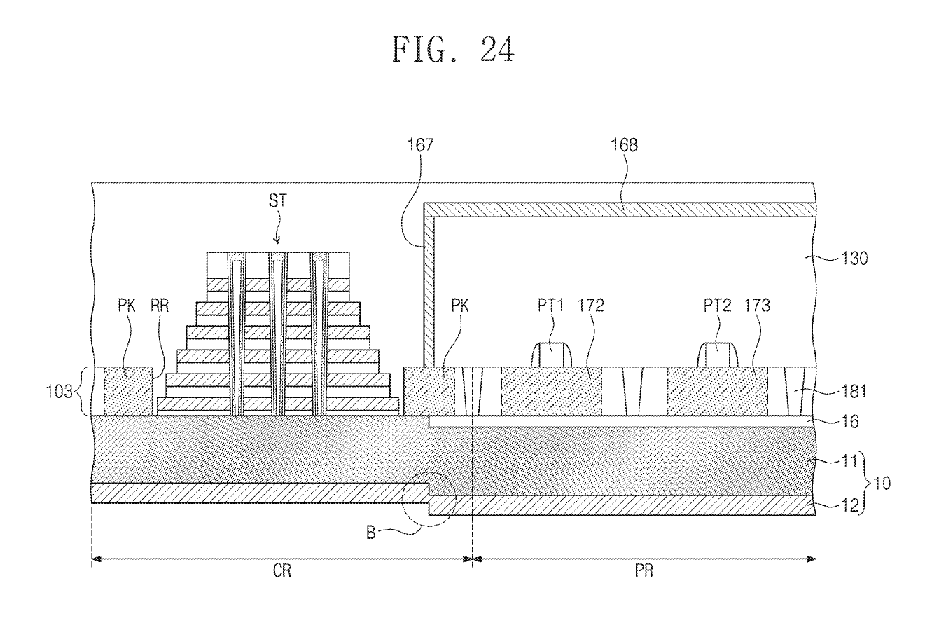

The peripheral circuit region PR may include peripheral transistors PT on a residual substrate 103. The peripheral transistors PT may include a peripheral impurity region 171 and gate electrodes on the peripheral impurity region 171. The peripheral transistors PT may include a PMOS transistor and/or an NMOS transistor, and the peripheral impurity region 171 may have conductivity of which conductive type is determined based on a type of transistor. The conductivity of the peripheral impurity region 171 will be further discussed in detail below with reference to FIGS. 23 and 24.

The residual substrate 103 may include a top surface 103a on which the gate electrodes are formed and a bottom surface 103b opposite the top surface 103a. For example, the residual substrate 103 may have a thickness T2, a distance between the top and bottom surfaces 103a and 103b, ranging from about 50 nm to about 1000 μm. A bottom surface of the peripheral impurity region 171 may be spaced apart from the bottom surface 103b of the residual substrate 103.

The residual substrate 103 may be originated from a semiconductor substrate, or a semiconductor wafer. For example, the residual substrate 103 may be a substantially single crystalline silicon layer. In this description, the term “substantially single crystalline” may mean that an object has the same crystallographic orientation without any grain boundaries. The term “substantially single crystalline” may also indicate that an object or portion is virtually single crystalline even if there are locally grain boundaries or different orientations. For example, the substantially single crystalline layer may include a plurality of low angle grain boundaries.

According to some example embodiments of inventive concepts, the peripheral circuit region PR may include a body conductive layer 10 below the residual substrate 103. The body conductive layer 10 may be in contact with the bottom surface 103b of the residual substrate 103, but inventive concepts are not limited thereto. The body conductive layer 10 may include a semiconductor material and/or a metallic material. For example, the body conductive layer 10 may include a polycrystalline semiconductor layer such as a polysilicon layer. The body conductive layer 10 may not be limited to the silicon layer, but may include a germanium layer, a silicon-germanium layer, etc. The body conductive layer 10 may be provided not only on the peripheral circuit region PR but on the cell array region CR. The body conductive layer 10 may have a thickness T1 less than the thickness T2 of the residual substrate 103. For example, the thickness T1 of the body conductive layer 10 may be in the range of about 5 nm to about 100 μm. The body conductive layer 10 may have first conductivity. For example, the first conductivity may be a p-type conductive type.

Interlayer dielectric layers 131, 132, 135, 136, and 137 may be provided to cover the peripheral transistors PT. For example, the interlayer dielectric layers 131, 132, 135, 136, and 137 may include a silicon oxide layer and/or a silicon oxynitride layer. At least one of the interlayer dielectric layers 131, 132, 135, 136, and 137 may be formed of a different material (e.g., silicon oxide versus silicon oxynitride, CVD oxide versus HDP oxide, etc.) than at least one other one of the interlayer dielectric layers 131, 132, 135, 136, and 137. At least one of the interlayer dielectric layers 131, 132, 135, 136, and 137 may be formed of a same material as at least one other one of the interlayer dielectric layers 131, 132, 135, 136, and 137. A peripheral contact 165 may be provided to penetrate first to third interlayer dielectric layers 131, 132, and 135, and may be connected to the peripheral transistor PT. A peripheral line PL may be provided in a fourth interlayer dielectric layer 136, and may be connected to the peripheral contact 165. The peripheral contact 165 and the peripheral line PL may include a conductive material such as doped silicon, metal, and conductive metal nitride.

The cell array region CR may include electrode structures ST, each of which includes gate electrodes GP that are sequentially stacked on the body conductive layer 10. Insulation layers 120 may be provided between the gate electrodes GP. For example, the gate electrodes GP and the insulation layers 120 may be alternately and repeatedly stacked on the body conductive layer 10. A buffer layer 111 may be provided between the body conductive layer 10 and a lowermost one of the gate electrodes GP. For example, the insulation layers 120 and the buffer layer 111 may include a silicon oxide layer and/or a silicon oxynitride layer. The buffer layer 111 may be thinner than the insulation layers 120.

For example, the lowermost one of the gate electrodes GP may be a gate electrode of a ground select transistor, e.g., a portion of the ground select line GSL of FIG. 1, and an uppermost one of the gate electrodes GP may be a gate electrode of a string select transistor, e.g., a portion of the string select line SSL of FIG. 1. Other ones between the lowermost and uppermost gate electrodes may be cell gate electrodes, e.g., portions of the word lines WL1 to WLn of FIG. 1. Although figures show that six gate electrodes GP are vertically stacked, the number of the gate electrodes GP may be more or less than that shown in figures.

Each of the gate electrodes GP in the electrode structures ST may extend in a first direction D1. The electrode structures ST may be spaced apart from each other in a second direction D2 across separation patterns 145. For example, separation trenches 141 may be provided in the electrode structures ST, and the separation patterns 145 may be provided in the separation trenches 141. Each of the separation patterns 145 may extend in the first direction D1. For example, the separation patterns 145 may include one or more of a silicon oxide layer, a silicon nitride layer, and a silicon oxynitride layer.

Common source lines 140 may be provided to penetrate the separation patterns 145 and may be connected to the body conductive layer 10. For example, each of the common source lines 140 may have a plate shape that extends along the first direction D1. Alternatively, the common source lines 140 may include a plurality of contacts each of which penetrates one separation pattern 145.

The common source lines 140 may include one or more of doped silicon, metal, and conductive metal nitride. For example, when the common source lines 140 include doped silicon, the common source lines 140 may have conductivity, or a second conductive type, different from that of the body conductive layer 10. For example, the second conductivity may be an n-type conductive type. Alternatively, when the common source lines 140 include a metallic material such as tungsten, titanium, tantalum, or any nitride thereof, the common source lines 140 and the body conductive layer 10 may be provided therebetween with additional metal silicide layer including tungsten silicide, etc.

Vertical structures VS may be provided to penetrate the electrode structures ST, and may be connected to the body conductive layer 10. Each of the vertical structures VS may have a circular pillar shape whose width decreases approaching its bottom from its top. The vertical structures VS may be two-dimensionally arranged on the body conductive layer 10. In this description, the term “two-dimensionally arranged” may mean that some components are arranged in a plurality of rows and columns along the first and second directions D1 and D2 that are perpendicular to each other. For example, one column may be made by a plurality of the vertical structures VS that are arranged along the first direction D1, and one electrode structure ST may be provided therein with a plurality of columns of the vertical structures ST. For example, as illustrated in FIG. 2A, four columns of the vertical structures VS may be disposed in one electrode structure ST, but this is only exemplary so that more or less than 4 columns may be disposed in one electrode structure ST. In some embodiments, the vertical structures VS on odd columns may be offset in the first direction D1 from the vertical structures VS on even columns.

As illustrated in FIGS. 3A and 3B, each of the vertical structures VS may include a buried insulation layer 139, a channel semiconductor layer CP, and a data storage layer DS. For example, the buried insulation layer 139 may be shaped identically or similarly to a circular pillar, and may be sequentially provided therein with the channel semiconductor layer CP and the date storage layer DS. Alternatively, no buried insulation layer 139 may be provided. For example, the buried insulation layer 139 may include a silicon oxide layer. The channel semiconductor layer CP may include a polycrystalline semiconductor material. The channel semiconductor layer CP may be intrinsic (undoped) or lightly doped with a first or second conductivity type impurity. For example, the channel semiconductor layer CP may include a polycrystalline silicon layer. Alternatively, the channel semiconductor layer CP may include a germanium layer or a silicon-germanium layer. In other embodiments, the channel semiconductor layer CP may be replaced with a nano-structure, such as carbon nano-tube or graphene, or with a conductive layer such as metal, conductive metal nitride, or silicide. The channel semiconductor layer CP may have a pipe shape with an open bottom.

The data storage layer DS may include a blocking insulation layer adjacent to the gate electrodes GP, a tunnel insulation layer adjacent to the channel semiconductor layer CP, and a charge storage layer between the blocking insulation layer and the tunnel insulation layer. The tunnel insulation layer may include a high-k dielectric layer, for example, a hafnium oxide layer or an aluminum oxide layer. The blocking insulation layer may be a multiple layer consisting of a plurality of thin layers. For example, the blocking insulation layer may include a first blocking insulation layer and a second blocking insulation layer, each of which may be an aluminum oxide layer and/or a hafnium oxide layer. The first and second blocking insulation layers may all extend in a vertical direction along the channel semiconductor layer CP, or alternatively, a portion of the first blocking insulation layer may extend between the gate electrodes GP and the insulation layers 120.

The charge storage layer may be a charge trap layer or an insulation layer including conductive nano-particles. The charge trap layer may include, for example, a silicon nitride layer. The tunnel insulation layer may include a silicon oxide layer and/or a high-k dielectric layer (e.g., a hafnium oxide layer or an aluminum oxide layer). The charge storage layer and the tunnel insulation layer may vertically extend along the channel semiconductor layer CP.

The data storage layer DS may have a pipe shape whose bottom and top ends are open. As illustrated in FIGS. 3A and 3B, the data storage layer DS, the channel semiconductor layer CP, and the buried insulation layer 139 may have respective bottom surfaces DSb, CPb, and 139b at substantially the same level or on substantially the same plane. For example, the bottom surface DSb of the data storage layer DS, the bottom surface CPb of the channel semiconductor layer CP, and the bottom surface 139b of the buried insulation layer 139 may be in contact with a top surface 10a of the body conductive layer 10. In other embodiments, the bottom surface DSb of the data storage layer DS, the bottom surface CPb of the channel semiconductor layer CP, and the bottom surface 139b of the buried insulation layer 139 may be located at their own levels that are differentiated based on a type of planarization process which will be discussed below.

The bottom surface CPb of the channel semiconductor layer CP may be substantially coplanar with the top surface 10a of the body conductive layer 10. An interface may be seen between the channel semiconductor layer CP and the body conductive layer 10, but inventive concepts are not limited thereto. As illustrated in FIG. 3A, the buffer layer 111 may have a bottom surface, which may be in contact with the top surface 10a of the body conductive layer 10 and may be located at the same level as those of the respective bottom surfaces DSb, CPb, and 139b of the data storage layer DS, the channel semiconductor layer CP, and the buried insulation layer 139. Alternatively, as illustrated in FIG. 3B, an etch stop layer 113 may be provided between the buffer layer 111 and the body conductive layer 10. The etch stop layer 113 may have a bottom surface, which may be in contact with the top surface 10a of the body conductive layer 10 and may be located at the same level as those of the respective bottom surfaces DSb, CPb, and 139b of the data storage layer DS, the channel semiconductor layer CP, and the buried insulation layer 139. For example, the etch stop layer 113 may include a metal oxide layer such as an aluminum oxide layer.

The vertical structures VS may include pad patterns 128 at or on their top portions. The pad patterns 128 may include polysilicon or metal. The pad patterns 128 may have sidewalls in contact with an inner surface of the data storage layer DS.

Bit lines BL may be provided on the vertical structures VS. The bit lines BL may each be connected in common to a plurality of the vertical structures VS. For brevity of description, all of the bit lines BL are not illustrated in FIG. 2A. The bit lines BL may be electrically connected through bit line contacts 164 to the vertical structures VS. A connection type between the bit lines BL and the vertical structures VS is not limited to that shown in FIG. 2A, but a variety of connection types are available. For example, subsidiary bit lines may be provided between the bit lines BL and the bit line contacts 164. The bit lines BL and the bit line contacts 164 may include one or more of metal (e.g., tungsten, copper, or aluminum), conductive metal nitride (e.g., titanium nitride or tantalum nitride), and transition metal (e.g., titanium or tantalum).

In a semiconductor memory device according to some example embodiments of inventive concepts, no residual substrate 103 may be provided on the cell array region CR. The vertical structures VS may be connected to the common source lines 140 through the body conductive layer 10 whose thickness is relatively small. As a result, a reduced thickness may be provided in a semiconductor memory device according to some example embodiments of inventive concepts. The thickness reduction may allow the semiconductor memory device to increase the number of stacked gate electrodes and/or of gate stacks including the stacked gate electrodes, thereby enhancing integration of the semiconductor memory device.

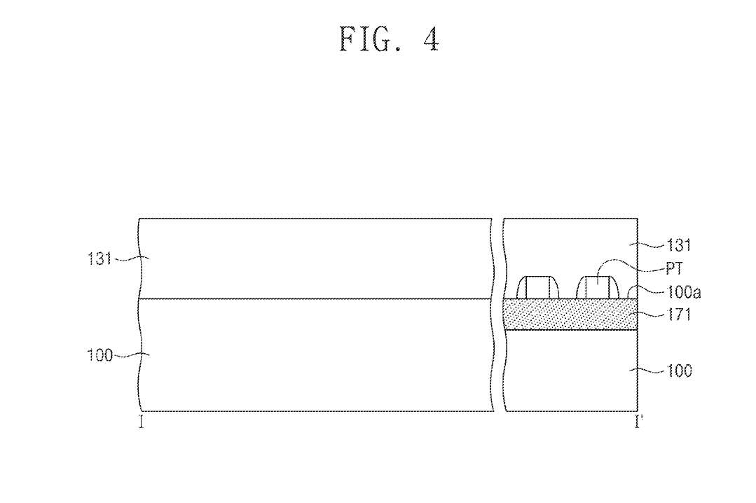

FIGS. 4 to 11 illustrate cross-sectional views taken along line I-I′ of FIG. 2A, showing a method of manufacturing a semiconductor memory device according to some example embodiments of inventive concepts.

Referring to FIGS. 2A and 4, a semiconductor substrate 100 may be provided to include a cell array region CR and a peripheral circuit region PR. For example, the semiconductor substrate 100 may be a single crystalline silicon substrate. The semiconductor substrate 100 may be doped with, for example, a first conductivity type impurity. The first conductivity may be a p-type conductive type. Peripheral transistors PT may be formed on the peripheral circuit region PR. The formation of the peripheral transistors PT may include forming a peripheral impurity region 171 and forming gate electrodes on the peripheral impurity region 171. Types of the peripheral transistors PT may determine conductivity of the peripheral impurity region 171. After the peripheral transistors PT are formed, a first interlayer dielectric layer 131 may be formed to cover the semiconductor substrate 100. For example, the first interlayer dielectric layer 131 may be formed of a silicon oxide layer.

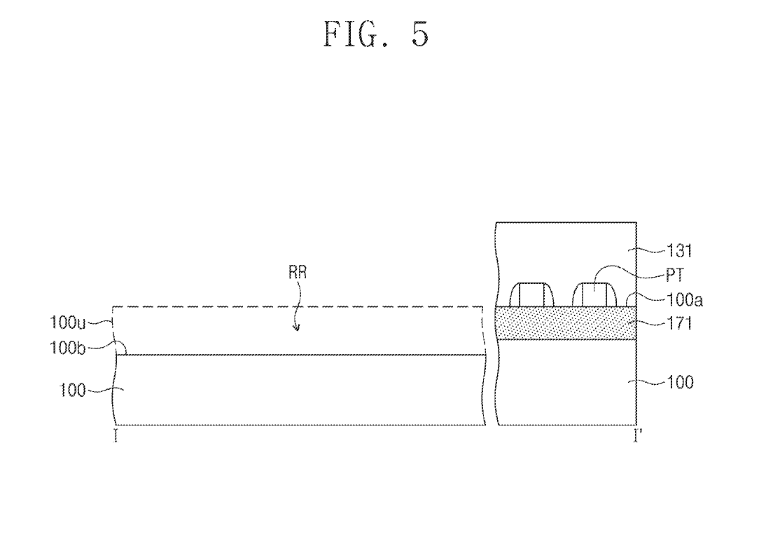

Referring to FIGS. 2A and 5, an upper portion 100u of the semiconductor substrate 100 on the cell array region CR may be removed to form a recess region RR. The formation of the recess region RR may result in step difference between a top surface 100b of the semiconductor substrate 100 on the cell array region CR and a top surface 100a of the semiconductor substrate 100 on the peripheral circuit region PR. For example, a thickness of the upper portion 100u removed from the semiconductor substrate 100 may be in the range of about 50 nm to about 1000 μm. The formation of the recess region RR may include forming on the semiconductor substrate 100 a mask pattern exposing the cell array region CR and performing an etching process on the first interlayer dielectric layer 131 and the semiconductor substrate 100 using the mask pattern as an etch mask. The etching process may include a plurality of dry or wet etching processes.

According to some example embodiments of inventive concepts, the etch stop layer 113 discussed with reference to FIG. 3B may be formed on the semiconductor substrate 100. The etch stop layer 113 may be formed substantially only on the cell array region CR. The etch stop layer 113 may include a material exhibiting an etch selectivity to all of insulation layers 120 and sacrificial layers 125 which will be discussed below. For example, the etch stop layer 113 may include a metal oxide layer such as an aluminum oxide layer. Alternatively, no etch stop layer 113 may be formed. The formation of the etch stop layer 113 may be performed in this step or may be preceded by the formation of a buffer layer 111 which will be discussed below.

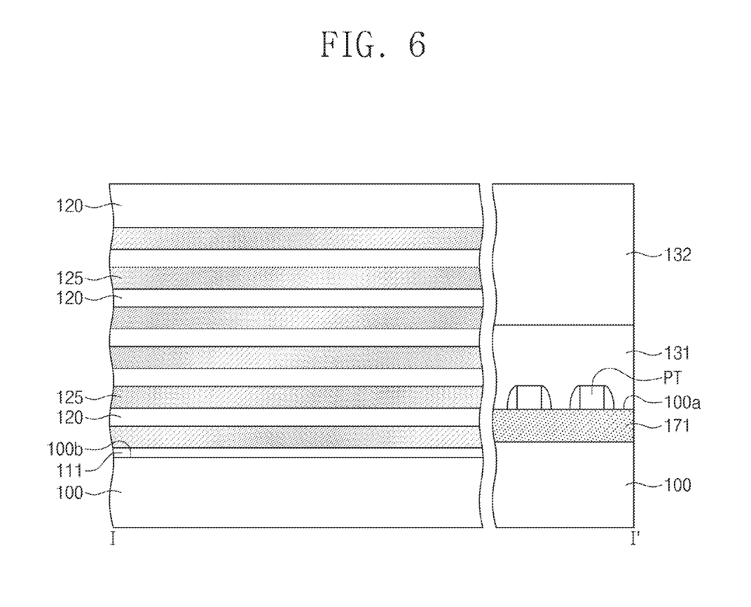

Referring to FIGS. 2A and 6, a buffer layer 111 may be formed on the cell array region CR, and then sacrificial layers 125 and insulation layers 120 may be alternately and repeatedly formed on the buffer layer 111. The buffer layer 111 may include a silicon oxide layer. For example, the buffer layer 111 may be formed by thermal oxidation. The sacrificial layers 125 and the insulation layers 120 may include materials exhibiting an etch selectivity to each other. For example, the sacrificial layers 125 may be formed of a material that may be etched while suppressing the insulation layers 120 from being etched when the sacrificial layers 125 are etched using a desired (and/or alternatively predetermined) etch recipe.

This etch selectivity may be quantitatively expressed as a ratio of an etch rate of the sacrificial layers 125 to an etch rate of the insulation layers 120. In some embodiments, the sacrificial layers 125 may include one of materials exhibiting an etch selectivity of about 1:10 to about 1:200 (more narrowly about 1:30 to about 1:100) with respect to the insulation layers 120. For example, the sacrificial layers 125 may include a silicon nitride layer, a silicon oxynitride layer, or a polysilicon layer, and the insulation layers 120 may include a silicon oxide layer. The sacrificial layers 125 and the insulation layers 120 may be formed by chemical vapor deposition (CVD). The sacrificial layers 125 and the insulation layers 120 may be formed on the peripheral circuit region PR and then removed from the peripheral circuit region PR. Thereafter, a second interlayer dielectric layer 132 may be formed to cover the peripheral circuit region PR. For example, the second interlayer dielectric layer 132 may include a silicon oxide layer, but is not limited thereto.

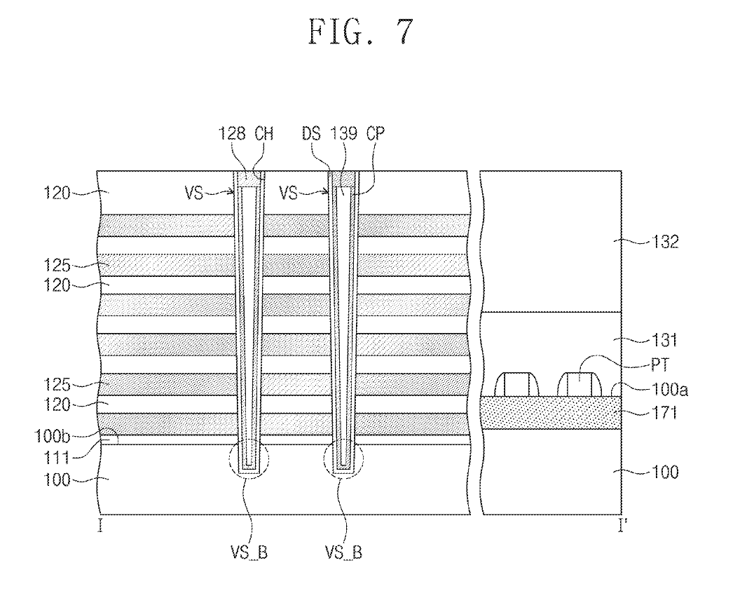

Referring to FIGS. 2A and 7, vertical structures VS may be formed to penetrate the sacrificial layers 125 and the insulation layers 120 and to be connected to the semiconductor substrate 100. An anisotropic etching process may be performed to form vertical holes CH that penetrate the sacrificial layers 125 and the insulation layers 120 and expose the semiconductor substrate 100, and then a deposition process may be performed to sequentially deposit a data storage layer DS, a channel semiconductor layer CP, and a buried insulation layer 139 in each of the vertical holes CH, thereby forming the vertical structures VS. The data storage layer DS, the channel semiconductor layer CP, and the buried insulation layer 139 may be configured the same as that discussed with reference to FIGS. 3A and 3B, and may be formed by one or more of chemical vapor deposition, atomic layer deposition, and sputtering. The data storage layer DS and the channel semiconductor layer CP may be conformally formed along a sidewall and a floor surface of the vertical hole CH. The buried insulation layer 139 may completely fill the vertical hole CH. Upper portions of the buried insulation layer 139 and the channel semiconductor layer CP may removed, and then pad patterns 128 may be formed to fill the removed upper portions. The pad patterns 128 may include metal or doped polysilicon.

The vertical structures VP may have lower portions VS_B inserted into an upper portion of the semiconductor substrate 100. For example, when the vertical holes CH are formed, floor surfaces of the vertical holes CH may be over-etched below the top surface 100b of the semiconductor substrate 100, and as a result, the lower portions VS-B of the vertical structures VS may be embedded in the upper portion of the semiconductor substrate 100. A lower portion of the channel semiconductor layer CP may be surrounded by the data storage layer DS in each lower portion VS_B of the vertical structures VS. The channel semiconductor layer CP may be spaced apart from the semiconductor substrate 100 across the data storage layer DS.

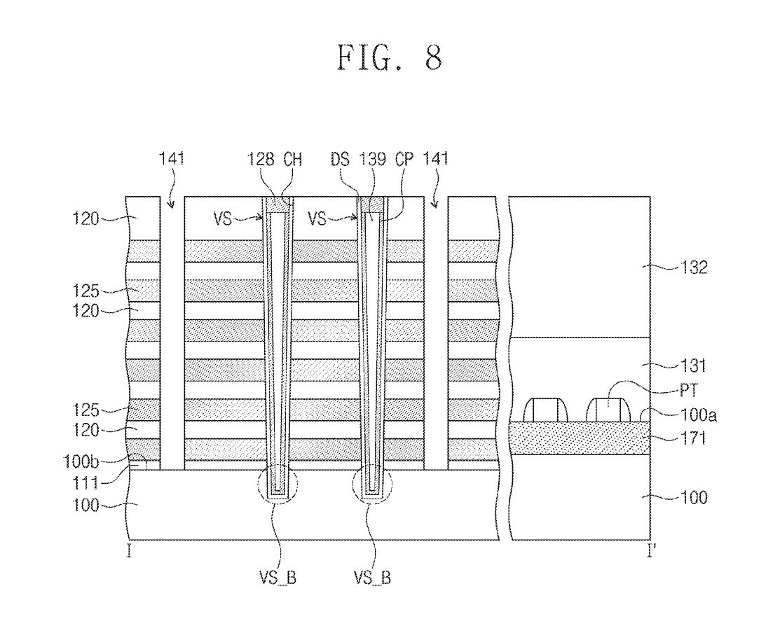

Referring to FIGS. 2A and 8, separation trenches 141 may be formed to penetrate the sacrificial layers 125 and the insulation layers 120. The separation trenches 141 may expose the top surface 100b of the semiconductor substrate 100, but inventive concepts are not limited thereto. The buffer layer 111 or the etch stop layer 113, which is discussed with reference to FIG. 3B, may remain in the separation trenches 141. The separation trenches 141 may be formed by an anisotropic etching process.

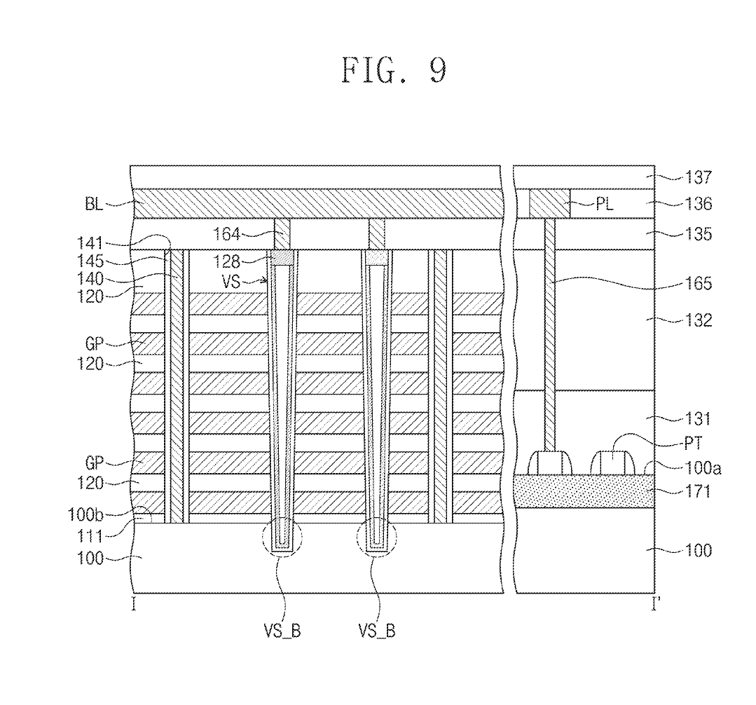

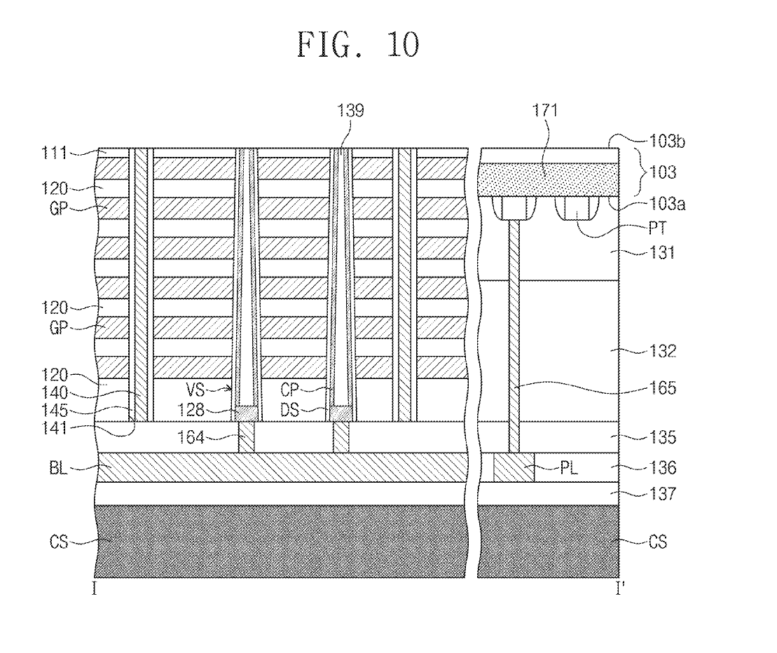

Referring to FIGS. 2A and 9, the sacrificial layers 125 may be replaced with gate electrodes GP. For example, a process may be performed to remove the sacrificial layers 125 exposed to the separation trenches 141, and the gate electrodes GP may be formed in spaces where the sacrificial layers 125 are removed. An etchant including phosphoric acid may be used to remove the sacrificial layers 125. In some embodiments, before the gate electrodes GP are formed, a blocking insulation layer may be conformally formed in the space where the sacrificial layers 125 are removed.

The separation trenches 141 may be provided therein with common source lines 140 that penetrate the separation patterns 145 and are connected to the semiconductor substrate 100. The common source lines 140 may be formed to have a plate shape that extends along the first direction D1. For example, the separation patterns 145 may be formed to have space shapes that cover sidewalls of the separation trenches 141, and the common source lines 140 may be formed to fill the separation trenches 141. Alternatively, contact holes may be formed to penetrate the separation patterns 145, and the common source lines 140 may be formed to fill the contact holes. The separation patterns 145 may be formed of one or more of a silicon oxide layer, a silicon nitride layer, and a silicon oxynitride layer. The common source lines 140 may be formed of one or more of doped silicon, metal, and conductive metal nitride.

For example, when the common source lines 140 include doped silicon, the common source lines 140 may be in-situ doped to have conductivity, a second conductive type, different from that of the semiconductor substrate 100. For example, the second conductivity may be an n-type conductive type.

A third interlayer dielectric layer 135 and a fourth interlayer dielectric layer 136 may be formed to cover the cell array region CR and the peripheral circuit region PR. Bit line contacts 164 may be formed to penetrate the third interlayer dielectric layer 135 and to be connected to the vertical structures VS, and a peripheral contact 165 may be formed to penetrate the first to third interlayer dielectric layers 131, 132, and 135 and to be connected to the peripheral transistor PT. Bit lines BL and a peripheral line PL may be formed in the fourth interlayer dielectric layer 136. A fifth interlayer dielectric layer 137 may be formed to cover the bit lines BL and the peripheral line PL. The third to fifth interlayer dielectric layers 135, 136, and 137 may be formed of a silicon oxide layer, but are not limited thereto. The bit lines BL, the peripheral line PL, and the contacts 164 and 165 may be formed of one of metal (e.g., tungsten, copper, or aluminum), conductive metal nitride (e.g., titanium nitride or tantalum nitride), and transition metal (e.g., titanium or tantalum).

Referring to FIGS. 2A and 10, a removal process may be performed to remove the semiconductor substrate 100. A carrier substrate CS may be provided on the fifth interlayer dielectric layer 137, and a bottom surface of the semiconductor substrate 100 may be turned to face upward prior to the removal process of the semiconductor substrate 100. The carrier substrate CS may be an insulating substrate, such as glass, or a conductive substrate, such as metal. For example, the carrier substrate CS may be adhered to the fifth interlayer dielectric layer 137 with an adhesive tape and/or a glue layer therebetween.

The removal process of the semiconductor substrate 100 may include chemical mechanical polishing. The removal process of the semiconductor substrate 100 may expose the channel semiconductor layer CP. For example, when the semiconductor substrate 100 is removed, a portion of the data storage layer DS surrounding the channel semiconductor layer CP may be removed to expose an end portion of the channel semiconductor layer CP. In some embodiments, the removal process of the semiconductor substrate 100 may be performed until the lower portions VS_B of the vertical structures VS illustrated in FIG. 9 are removed.

The removal process of the semiconductor substrate 100 may remove the semiconductor substrate 100 from the cell array region CR. Accordingly, on the cell array region CR, the buffer layer 111 may be exposed, or the etch stop layer 113 discussed with reference to FIG. 3B may be exposed. Because the semiconductor substrate 100 has experienced the formation of the recess region RR discussed with reference to FIG. 5, the semiconductor substrate 100 may be caused to leave its portion (referred to hereinafter as a residual substrate 103) on the peripheral circuit region PR. The residual substrate 103 may include an exposed bottom surface 103b and a top surface 103a opposite the bottom surface 103b.

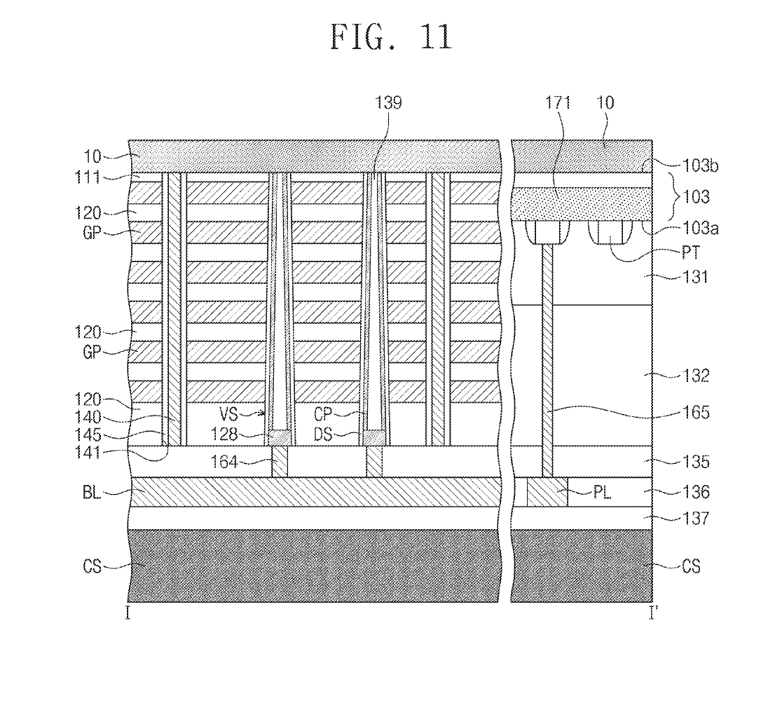

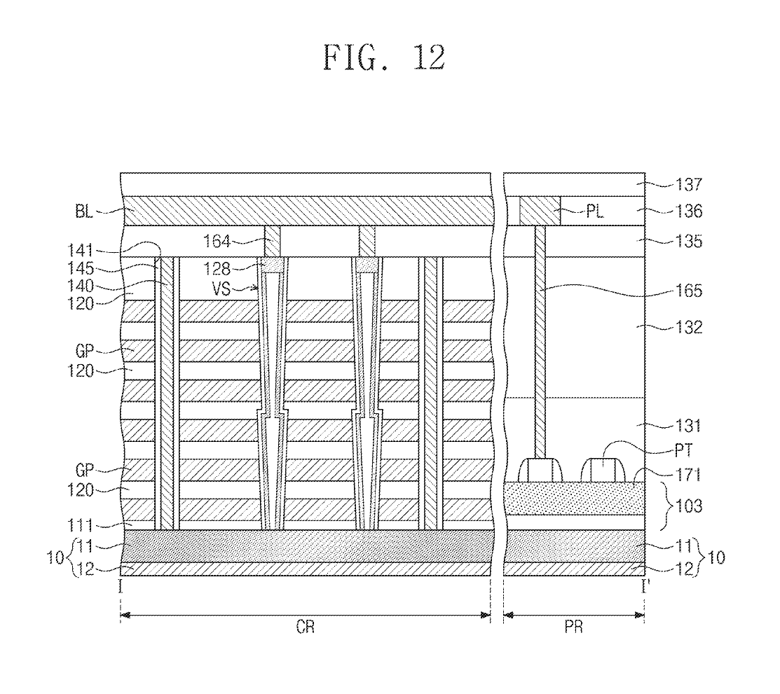

Referring to FIGS. 2A and 11, a body conductive layer 10 may be formed to cover the cell array region CR and the peripheral circuit region PR. The body conductive layer 10 may include a semiconductor material and/or a metallic material. For example, the body conductive layer 10 may be formed of polysilicon. The body conductive layer 10 may be in-situ doped to have first conductivity. The body conductive layer 10 may be formed by chemical vapor deposition or atomic layer deposition. For example, the formation of the body conductive layer 10 may include forming an amorphous silicon layer and performing an annealing process on the amorphous silicon layer. The annealing process may be performed at a temperature of about 700° C. to about 1000° C. For example, the body conductive layer 10 may have a thickness ranging from 5 nm to about 100 μm. The carrier substrate CS may then be removed, thereby manufacturing a semiconductor memory device as discussed with reference to FIGS. 2A and 2B.

On the peripheral circuit region PR, the body conductive layer 10 may be formed on the bottom surface 103b of the residual substrate 103. On the cell array region CR, the body conductive layer 10 may be connected to the channel semiconductor layer CP. For example, the body conductive layer 10 may be in direct contact with the channel semiconductor layer CP.

With increasing height of vertical semiconductor memory devices, the processing difficulty is increasing in electrical connection between the channel semiconductor layers and the semiconductor substrate. For example, a manufacturing process may include an operation to remove at least a portion of the data storage layer to electrically connect the channel semiconductor layers to the semiconductor substrate. According to some example embodiments of inventive concepts, the semiconductor substrate 100 may be removed from the cell array region CR and at the same time the channel semiconductor layers CP may be exposed, such that the body conductive layer 10 may be connected to the channel semiconductor layers CP with no separate etching process and thus the manufacturing process may be simplified.

FIGS. 12 to 19 illustrate cross-sectional views taken along line I-I′ of FIG. 2A, showing a semiconductor memory device according to some example embodiments of inventive concepts. For brevity of description, explanations of duplicate components will be omitted.

Referring to FIG. 12, a polycrystalline semiconductor layer 11 and a metal layer 12 may be included in the body conductive layer 10 of a semiconductor memory device according to some example embodiments of inventive concepts. The metal layer 12 may be spaced apart from the vertical structures VS across the polycrystalline semiconductor layer 11. The polycrystalline semiconductor layer 11 may be substantially the same as the polycrystalline semiconductor layer discussed with reference to FIG. 2B. For example, the polycrystalline semiconductor layer 11 may be a polycrystalline silicon layer. The metal layer 12 may include one or more of tungsten, titanium, tantalum, and any conducive nitride thereof. The metal layer 12 may be formed thinner the polycrystalline semiconductor layer 11. For example, the metal layer 12 may be formed by sputtering. In some embodiments, a plurality of etching processes may be performed to form vertical holes for forming the vertical structures VS, and as a result, the vertical structures VS may have portions whose width increases or decreases discontinuously.

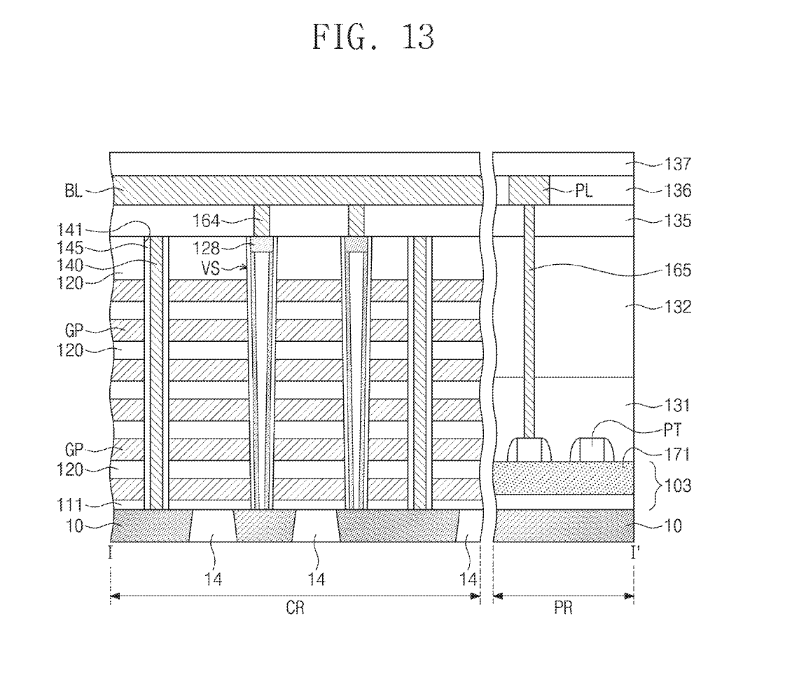

Referring to FIG. 13, insulation patterns 14 may be included in the body conductive layer 10 of a semiconductor memory device according to some example embodiments of inventive concepts. For example, the insulation patterns 14 may penetrate the body conductive layer 10. The insulation patterns 14 may have a linear shape that extends along the first direction D1 of FIG. 2A, but inventive concepts are not limited thereto. The insulation patterns 14 may include one or more of silicon oxide, silicon nitride, and silicon oxynitride. The formation of the insulation patterns 14 may include forming the body conductive layer 10, etching the body conductive layer 10 to form trenches, and filling the trenches with an insulating material.

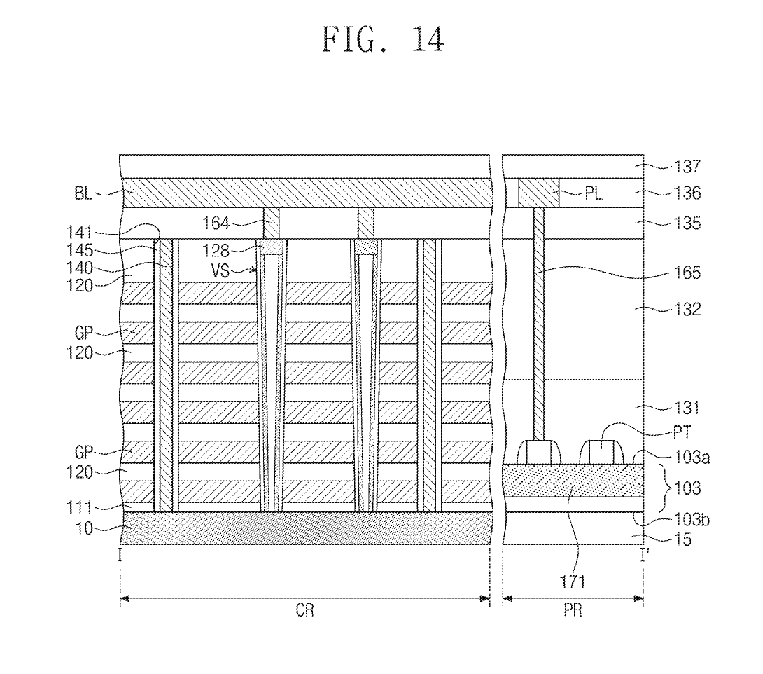

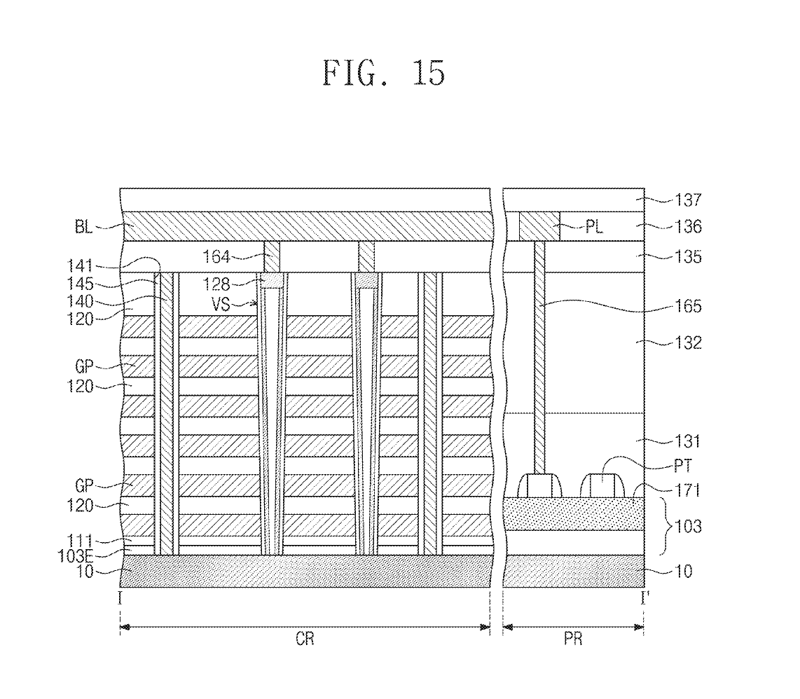

Referring to FIG. 14, the peripheral circuit region PR may be provided with a layer whose type is different from that of the body conductive layer 10. For example, an insulation pattern 15 may be provided to contact the bottom surface 103b of the residual substrate 103. The insulation pattern 15 may include one or more of silicon oxide, silicon nitride, and silicon oxynitride. The formation of the insulation pattern 15 may include removing the body conductive layer 10 on the peripheral circuit region PR to form a space on the peripheral circuit region PR and filling the space with an insulating material.

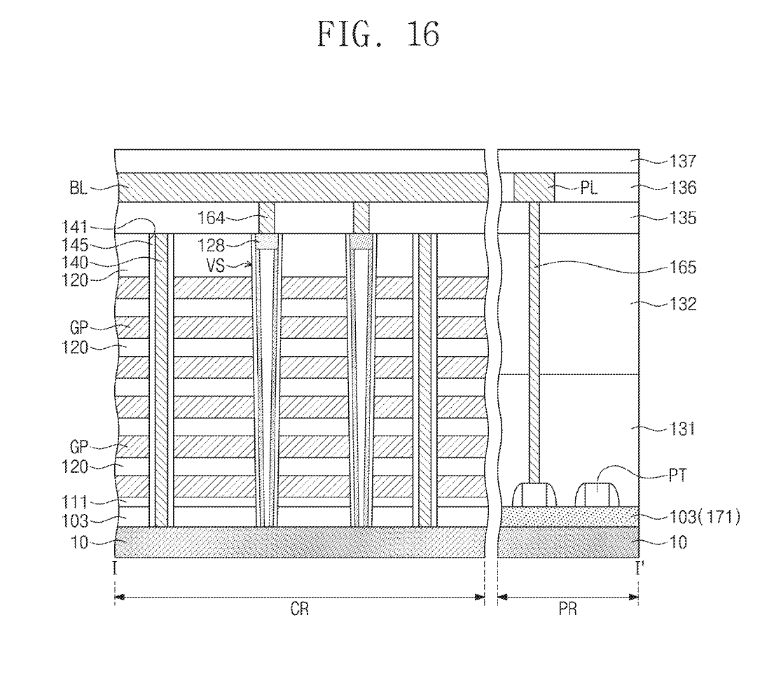

Referring to FIG. 15, the residual substrate 103 may extend onto the cell array region CR from the peripheral circuit region PR. For example, the residual substrate 103 may leave a remaining portion 103E on the cell array region CR. The residual substrate 103 on the peripheral circuit region PR may have a thickness greater than that of the remaining portion 103E on the cell array region CR. The above structural feature may be obtained by adjusting the chemical mechanical polishing discussed with reference to FIG. 10.

Referring to FIG. 16, the residual substrate 103 may extend onto the cell array region CR from the peripheral circuit region PR. The cell array region CR and the peripheral circuit region PR may be provided thereon with the semiconductor substrate 100 having substantially the same thickness. The above structural feature may be acquired when skipping the formation of the recess region RR discussed with reference to FIG. 5.

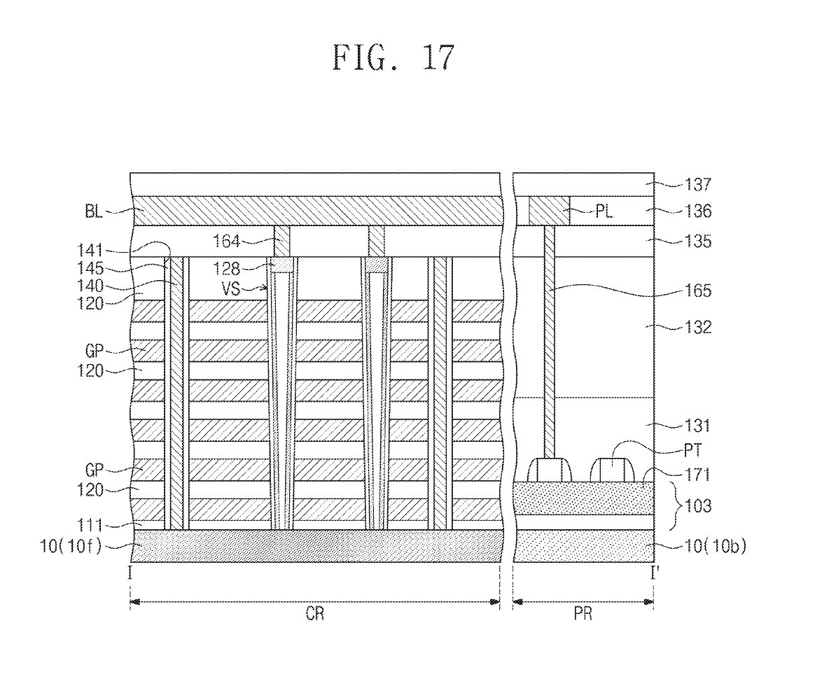

Referring to FIG. 17, according to some example embodiments of inventive concepts, the body conductive layer 10 may have a different impurity concentration between the cell array region CR and the peripheral circuit region PR. For example, an impurity concentration of a body conductive layer 10f on the cell array region CR may be greater than an impurity concentration of a body conducive layer 10b on the peripheral circuit region PR. For example, the impurity concentration of the body conductive layer 10f on the cell array region CR may be about 5 times to about 10 times greater than the impurity concentration of the body conductive layer 10b on the peripheral circuit region PR. The body conductive layer 10f may be formed and then partially removed to form the body conductive layer 10b of the peripheral circuit region PR.

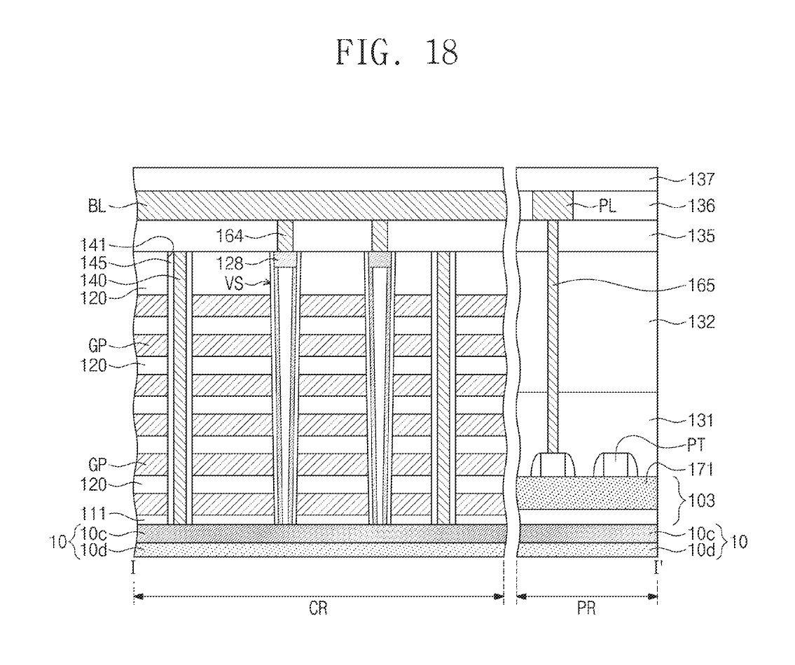

Referring to FIG. 18, according to some example embodiments of inventive concepts, the body conductive layer 10 may include a first semiconductor layer 10c and a second semiconductor layer 10d that have different impurity concentrations from each other. The second semiconductor layer 10d may be spaced apart from the vertical structures VS across the first semiconductor layer 10c. The first semiconductor layer 10c may have an impurity concentration greater than that of the second semiconductor layer 10d. For example, the impurity concentration of the first semiconductor layer 10c may be about 5 times to about 100 times greater than the impurity concentration of the second semiconductor layer 10d. The first and second semiconductor layers 10c and 10d may be formed to have different impurity concentrations by adjusting an impurity doping concentration in an in-situ process.

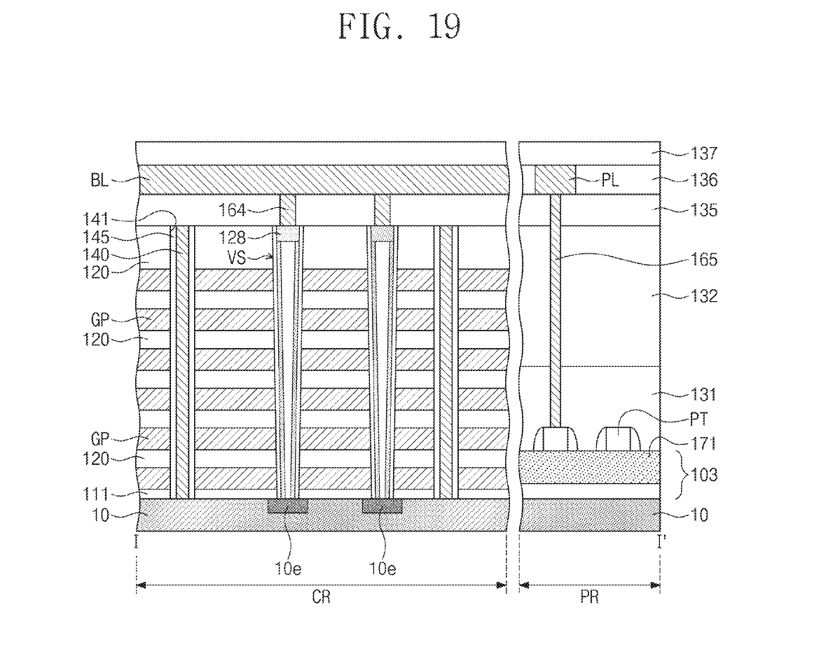

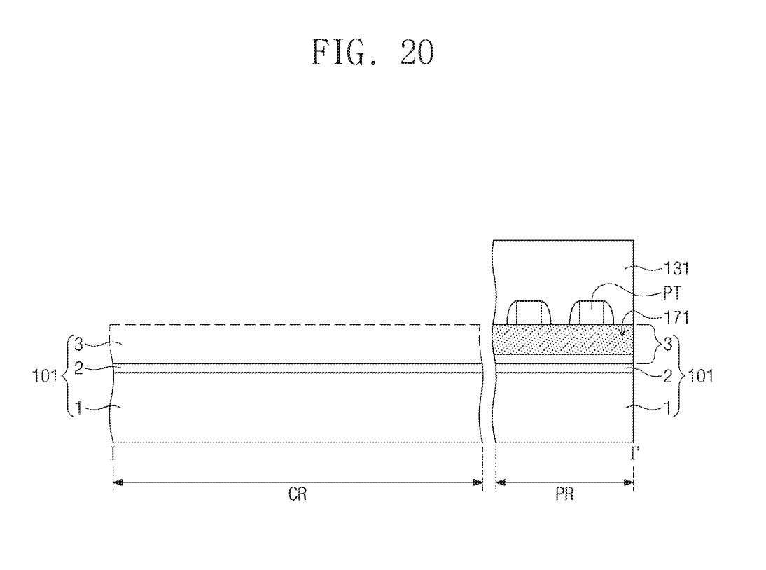

Referring to FIG. 19, according to some example embodiments of inventive concepts, the body conductive layer 10 may include impurity regions 10e that are locally formed therein. For example, the impurity regions 10e may be formed below the vertical structures VS. After the body conductive layer 10 is formed, an ion implantation process may be performed to form the impurity regions 10e. The impurity regions 10e may each have an impurity concentration greater than that of the body conductive layer 10. For example, each impurity concentration of the impurity regions 10e may be about 5 times to about 100 times greater than the impurity concentration of the body conductive layer 10.

FIGS. 20 to 22 illustrate cross-sectional views taken along line I-I′ of FIG. 2A, showing a method of manufacturing a semiconductor memory device according to some example embodiments of inventive concepts. For brevity of description, explanations of duplicate components will be omitted.

Referring to FIGS. 2A and 20, a semiconductor substrate 101 may be provided. The semiconductor substrate 101 may include therein an insulation layer. For example, the semiconductor substrate 101 may be an SOI (Silicon On Insulator) substrate or a GOI (Germanium On Insulator) substrate. The semiconductor substrate 101 may include a lower semiconductor layer 1, an upper semiconductor layer 3, and a middle insulation layer 2 between the lower and upper semiconductor layers 1 and 3. Peripheral transistors PT and a first interlayer dielectric layer 131 covering the peripheral transistors PT may be formed on a peripheral circuit region PR, and then the upper semiconductor layer 3 may be removed from a cell array region CR. As a result, the middle insulation layer 2 may be exposed on the cell array region CR.

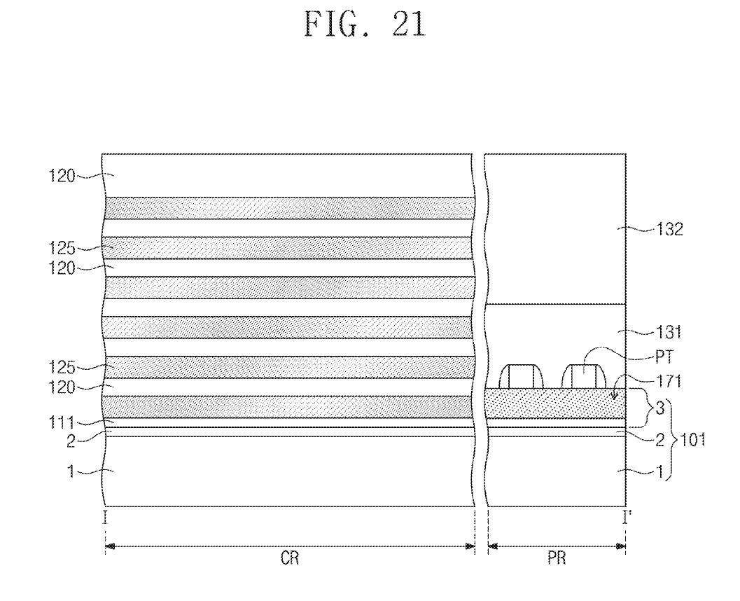

Referring to FIGS. 2A and 21, a buffer layer 111 may be formed on the middle insulation layer 2 exposed on the cell array region CR, and then sacrificial layers 125 and insulation layers 120 may be alternately and repeatedly formed on the buffer layer 111. Thereafter, a second interlayer dielectric layer 132 may be formed to cover the peripheral circuit region PR.

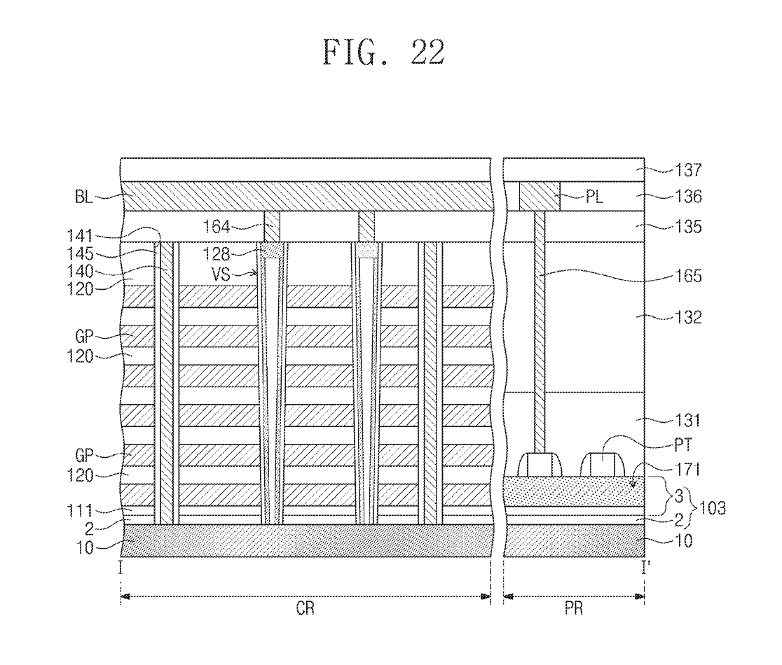

Referring to FIGS. 2A and 22, processes substantially the same as those discussed with reference to FIGS. 7 to 11 may be performed, thereby manufacturing a semiconductor memory device. The semiconductor memory device may include a residual substrate 103 originated from at least a remaining portion of the semiconductor substrate 101. For example, on the cell array region CR, at least a portion of the middle insulation layer 2 may remain between the body conductive layer 10 and the buffer layer 111, and on the peripheral circuit region PR, the upper semiconductor layer 3 may remain on the middle insulation layer 2. The middle insulation layer 2 may act as an etch stop layer when the lower semiconductor layer 1 is removed. For example, the remaining upper semiconductor layer 3 may have a thickness ranging from 5 nm to about 1000 μm.

FIGS. 23 to 24 illustrate cross-sectional views showing a method of manufacturing a semiconductor memory device according to some example embodiments of inventive concepts. For brevity of description, explanations of duplicate components will be omitted.

Referring to FIG. 23, a semiconductor substrate 100 may be provided to include a cell array region CR and a peripheral circuit region PR. Device isolation layers 181 may be provided at or on an upper portion of the semiconductor substrate 100. A first impurity region 174 may be formed on the cell array region CR, and a second impurity region 172 and a third impurity region 173 may be formed on the peripheral circuit region PR. For example, the first and second impurity regions 174 and 172 may be substantially the same impurity region, and the third impurity region 173 may be an impurity region whose conductivity is different from that of the first and second impurity regions 174 and 172. A first peripheral transistor PT1 may be formed on the second impurity region 172, and a second peripheral transistor PT2 may be formed on the third impurity region 173. For example, the first peripheral transistor PT1 may be an NMOS transistor, and the second peripheral transistor PT2 may be a PMOS transistor. The device isolation layers 181 may be formed between the cell array region CR and the peripheral circuit region PR and between the first peripheral transistor PT1 and the second peripheral transistor PT2.

Referring to FIG. 24, a recess region RR may be formed at or on the upper portion of the semiconductor substrate 100, and then processes substantially the same as those discussed with reference to FIGS. 6 to 11 may be performed. As a result, a body conductive layer 10 and an electrode structure ST may be formed on the cell array region CR. The recess region RR may be exposed when the semiconductor substrate 100 experiences the removal process discussed with reference to FIG. 10, and thus a thorough region may be formed on the cell array region CR. After the recess region RR is formed, a portion of the first impurity region 174 may remain on the cell array region CR to create a pick-up impurity region PK. The pick-up impurity region PK may have an impurity concentration the same as or higher than that of the body conductive layer 10. The pick-up impurity region PK may be provided to supply the body conductive layer 10 with voltage. For example, a contact 167 and an electric line 168, which are connected to the pick-up impurity region PK, may be provided in an interlayer dielectric layer 130 that covers the cell array region CR and the peripheral circuit region PR.

In some embodiments, after the semiconductor substrate 100 is removed and before the body conductive layer 10 is formed, an insulation pattern 16 may be formed to cover a bottom surface of the residual substrate 103. The insulation pattern 16 may be connected to the device isolation layers 181. The insulation pattern 16 may separate the second and third impurity regions 172 and 173 from their underlying body conductive layer 10. For example, the insulation patterns 16 may include one or more of silicon oxide, silicon nitride, and silicon oxynitride.

The formation of the insulation pattern 16 may cause the body conductive layer 10 to have a stepwise structure B between the cell array region CR and the peripheral circuit region PR. The body conductive layer 10 may include the polycrystalline semiconductor layer 11 and the metal layer 12 as discussed with reference to FIG. 12, but inventive concepts are not limited thereto.

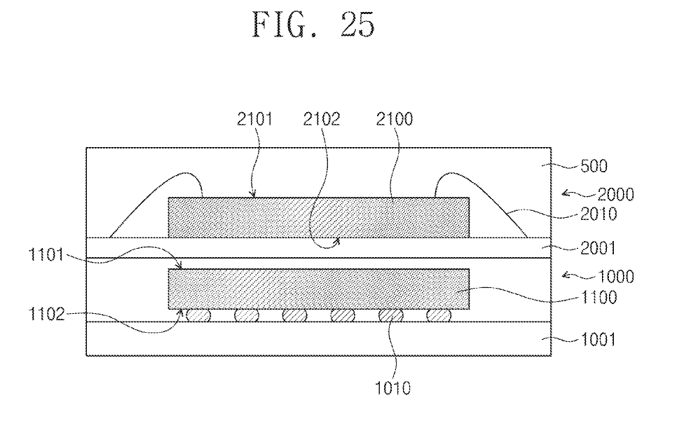

FIG. 25 illustrates a cross-sectional view showing a semiconductor package according to some example embodiments of inventive concepts. For brevity of description, explanations of duplicate components will be omitted.

Referring to FIG. 25, a plurality of semiconductor packages may be included in a semiconductor package according to some example embodiments of inventive concepts. For example, a first package 1000 and a second package 2000 may be sequentially stacked in a semiconductor memory device according to some example embodiments of inventive concepts. The first package 1000 may include a first semiconductor chip 1100 mounted on a first package substrate 1001. The second package 2000 may include a second semiconductor chip 2100 mounted on a second package substrate 2001. The first and second semiconductor chips 1100 and 2100 may be encapsulated by a molding layer 500 such as epoxy resin. The first and second package substrates 1001 and 2001 may be a printed circuit board.

One or more of the first and second semiconductor chips 1100 and 2100 may be a semiconductor memory device according to some example embodiments to inventive concepts. For example, the first and second semiconductor chips 1100 and 2100 may be the semiconductor memory device discussed with reference to FIGS. 2A and 2B.

The first semiconductor chip 1100 may be flip-chip mounted through bumps 1010 on the first package substrate 1001. For example, the first semiconductor chip 1100 may include a first surface 1101 and a second surface 1102, and the first surface 1101 may be adjacently provided with the body conductive layer according to some example embodiments of inventive concepts. The second semiconductor chip 2100 may be connected through wires 2010 to the second package substrate 2001. For example, the second semiconductor chip 2100 may include a first surface 2101 and a second surface 2102, and the second surface 2102 may be adjacently provided with the body conductive layer according to some example embodiments of inventive concepts. The above mount type of the first and second semiconductor chips 1100 and 2100 may be only exemplary, and more than two semiconductor chips may be differently mounted.

According to some example embodiments of inventive concepts, a semiconductor memory device may decrease in thickness, and thereby it may be easily to manufacture a semiconductor package including a plurality of semiconductor chips.

Furthermore, it may be provided simplified methods of manufacturing a semiconductor memory device.

Although some example embodiments of inventive concepts have been discussed with reference to accompanying figures, it will be understood that various changes in form and details may be made therein without departing from the spirit and scope of inventive concepts. Furthermore, it is understood that several elements of each embodiments may be combined with each other or replaced by other to form alternative embodiments that lead to the same result.

1. A semiconductor memory device comprising:
a cell array region connected to a peripheral circuit region,
the cell array region including a plurality of electrode structures and a plurality of vertical structures on a body conductive layer, the plurality of electrode structures each including a plurality of electrodes that are sequentially stacked on the body conductive layer, the plurality of vertical structures penetrating the plurality of electrode structures and being connected to the body conductive layer,
the peripheral circuit region including a peripheral transistor on a residual substrate, and
a top surface of the residual substrate being higher than a top surface of the body conductive layer.

2. The semiconductor memory device of claim 1, wherein the body conductive layer extends below the residual substrate.

3. The semiconductor memory device of claim 1, wherein a thickness of the body conductive layer is less than a thickness of the residual substrate.

4. (canceled)

5. The semiconductor memory device of claim 1, wherein
each of the plurality of vertical structures includes a channel semiconductor layer and a data storage layer, and
the body conductive layer is connected to the channel semiconductor layer.

6. The semiconductor memory device of claim 5, wherein a bottom surface of the channel semiconductor layer is at the same level as a bottom surface of the data storage layer.

7. The semiconductor memory device of claim 1, further comprising:
an etch stop layer between the plurality of electrode structures and the body conductive layer,
wherein the plurality of vertical structures penetrate the etch stop layer.

8. The semiconductor memory device of claim 1, further comprising:
a common source conductive line that extends between the plurality of electrode structures, wherein
the common source conductive line is connected to the body conductive layer.

9. The semiconductor memory device of claim 1, wherein
the body conductive layer includes a polycrystalline semiconductor layer and a metal layer, and
the metal layer is spaced apart from the plurality of vertical structures across the polycrystalline semiconductor layer.

10. The semiconductor memory device of claim 1, further comprising:
a plurality of insulation patterns lying in and penetrating through the body conductive layer.

11. The semiconductor memory device of claim 1, further comprising:
an insulation pattern below the residual substrate such that the residual substrate is on the insulation pattern,
wherein the body conductive layer is locally provided in the cell array region.

12. The semiconductor memory device of claim 1, wherein, on the cell array region, the residual substrate extends between the body conductive layer and the plurality of electrode structures.

13. The semiconductor memory device of claim 12, wherein the residual substrate is thicker on the peripheral circuit region than on the cell array region.

14. The semiconductor memory device of claim 1, wherein
the body conductive layer extends below the residual substrate, and
the body conductive layer has a greater impurity concentration on the cell array region than on the peripheral circuit region.

15. The semiconductor memory device of claim 1, wherein
the body conductive layer includes a first semiconductor layer and a second semiconductor layer,
the first semiconductor layer is adjacent to the plurality of vertical structures,
the second semiconductor layer is spaced apart from the plurality of vertical structures across the first semiconductor layer,
the first semiconductor layer has an impurity concentration greater than that of the second semiconductor layer.

16. The semiconductor memory device of claim 1, wherein
the residual substrate extends onto the cell array region,
the residual substrate contacts the body conductive layer on the cell array region, and
the residual substrate in contact with the body conductive layer on the cell array region includes an impurity region whose doping concentration is greater than that of the body conductive layer.

17. The semiconductor memory device of claim 1, further comprising:
an insulation pattern on the residual substrate and the body conductive layer, wherein
the body conductive layer extends below the residual substrate.

18. The semiconductor memory device of claim 17, wherein the body conductive layer has a stepwise structure between the cell array region and the peripheral circuit region.

19. A semiconductor memory device, comprising:
a body conductive layer including a polycrystalline semiconductor material;
a plurality of electrode structures on the body conductive layer, the plurality of electrode structures including a plurality of electrodes that sequentially stacked on the body conductive layer;
a plurality of vertical structures that penetrate the plurality of electrode structures, the plurality of vertical structures being connected to the body conductive layer; and
a common conductive line that extends between the plurality of electrode structures, the common conductive line being connected to the body conductive layer.

20. The semiconductor memory device of claim 19, further comprising:
a residual substrate; and
a plurality of peripheral transistors on the residual substrate, wherein
the plurality of peripheral transistors are spaced apart from the plurality of vertical structures.

21. The semiconductor memory device of claim 20, wherein
the residual substrate includes a through region penetrating therethrough, and
the plurality of electrode structures are in the through region.

22.-30. (canceled)
